(19) United States
(12) Patent Application Publication
(10) Pub. No.: US 2012/0193801 A1
(43) Pub. Date: Aug. 2, 2012

(54) RFID TRANSPONDER AND METHOD FOR CONNECTING A SEMICONDUCTOR DIE TO AN ANTENNA

(75) Inventors: Johann Gross, Berglern (DE); Bernhard Lange, Freising (DE)

(73) Assignee: TEXAS INSTRUMENTS DEUTSCHLAND GMBH, Freising (DE)

(21) Appl. No.: 13/351,104

(22) Filed: Jan. 16, 2012

(30) Foreign Application Priority Data
Jan. 27, 2011 (DE) 10 2011 009 577.2

(51) Int. Cl. H01L 23/49; H01P 11/00; B23K 26/00; B23K 31/02; B23K 1/20

(52) U.S. Cl. 257/772; 228/173.5; 219/121.66; 29/600; 257/E23.025

(57) ABSTRACT

An RFID transponder having a semiconductor die with a solderable contact area and an antenna made from a winding wire, wherein the winding wire is soldered to the contact area, and the solderable contact area is made from a nickel based alloy.

### CROSS-REFERENCE TO RELATED APPLICATIONS

This patent application claims priority from German Patent Application No. 10 2011 009 577.2, filed Jan. 27, 2011, which is incorporated herein by reference in its entirety.

### FIELD OF THE INVENTION

The invention relates to an RFID transponder, comprising a semiconductor die and an antenna made from a winding wire. Further, the invention relates to a method for connecting a semiconductor die to an antenna winding wire.

### BACKGROUND OF THE INVENTION

Current wafers for transponder chips, especially for RFID HDX transponders, need expensive gold layers for contacting the same to a winding wire of an antenna. Further, the antenna's winding wire needs to be soldered manually which causes a long process time and additional costs. Soldering is typically performed by a thermo compression process that is known to create high thermal and mechanical stress to the respective material in the soldering area. Intrinsic stress may lead to degradation of the material properties in the connecting area. In the worst case, mechanic stress leads to cracks in the connection, and therefore, causes problems with respect to reliability of the electrical connection. A typical fixing process is exemplarily known from U.S. Pat. No. 5,572,410.

### SUMMARY OF THE INVENTION

It is a general object of the invention to provide an RFID transponder comprising a semiconductor die and an antenna made from a winding wire and a method for connecting a semiconductor die to the winding wire of an antenna offering reduced mechanical stress for the antenna to die connection.

In one aspect of the invention, an RFID transponder comprising a semiconductor die having a solderable contact area and an antenna made from a winding wire is provided. The winding wire is soldered to the contact area of the die, wherein the solderable contact area is made from a nickel based alloy. Preferably, the solderable contact area is a plating made from the nickel based alloy that is preferably a nickel gold alloy (NiAu) or a nickel tin alloy (NiSn). Further preferably, the solder contact between the winding wire and the contact area is realized with the help of laser soldering, hot stamping soldering or ultrasonic compression welding. The solder material is preferably lead and flux free.

According to the invention, the thermo compression process that is presently established in the art may be avoided. A solderable contact area without gold (Au) may be applied and the soldering process may become much more economic with respect to the material (gold) itself as well as with respect to processing. Instead of the conventional gold plating, a nickel based material is applied for providing the solderable contact area or contact pads, respectively.

Due to empirical analysis, it has been discovered that thermo compression induces mechanical stress in the connecting area. Connecting techniques like hot stamping soldering, ultrasonic compression welding and laser soldering significantly reduce the appearance of intrinsic stress. In combination with nickel based solderable contact area, a reliable connection between the winding wire of an antenna and the die may be provided. Mechanical stress in the connecting area is significantly reduced. The expensive gold layer in the contact area may be omitted which leads to more than 70% of cost saving. High temperatures of up to 700° C., that are typically known from the soldering process when using a gold thermo compression connecting process, do not occur when applying the aforementioned techniques.

According to another aspect of the invention, the solderable contact area comprises a tin (Sn) finish. This leads to further reduction of thermal and mechanical stress. In combination with the hot stamping solder process, empirical analysis showed that the tin finish provides a significant reduction of thermal and mechanical stress.

For ultrasonic compression welding, it was discovered that the thermal and mechanical stress to the die is more than 20% reduced compared to the gold thermo compression process known in the Art.

According to a further embodiment of the invention, the antenna's winding wire insulation is stripped off using a laser. The stripping of the wire's insulation has been identified as a further source for thermal stress. By stripping the wire insulation with the laser, the introduction of further thermal stress can be avoided.

In another embodiment of the invention, the contact between the winding wire and the solderable contact area is performed by using a lead and flux free solder material. Especially in combination with laser soldering, a flux free solder connection may be realized.

According to another aspect of the invention, a method for connecting a semiconductor die to a winding wire of an antenna is provided. The die has a solderable contact area made from a nickel based alloy. The step of soldering the winding wire to the solderable contact area is performed by using a hot stamping solder process or by ultrasonic compression welding. According to another aspect of the invention, the step of soldering the winding wire to the solderable contact area is performed by using a contact free connecting method, preferably by laser soldering.

Similarly, already mentioned for the RFID transponder according to the invention. Due to empirical analysis, it has been discovered that the aforementioned connecting techniques significantly reduce the appearance of intrinsic stress. Preferably, a thermo compression process may be avoided.

Preferably, if a laser is used for soldering, the step of stripping the antenna winding wire insulation is performed by also using the laser, preferably the same laser already in use for soldering is applied.

According to another aspect of the invention, the step of positioning the die and the antenna winding wire relative to each other is performed with the help of a positioning stage. The die may be picked by a usual die picker and set to a suitable sample jig that is mounted to the positioning stage. A plurality of different dies may be soldered by using solely one positioning stage since the latter is positionable. The positioning step is performed automatically.

In another embodiment of the invention, the die is mounted to the positioning stage with the help of a vacuum holder. This allows a very flexible fixation of the die. Further preferably, the method comprises the step of heating the positioning stage. This supports the soldering process made by, i.e., a laser. A preferable solder alloy for the method according to the invention is lead and flux free.

### BRIEF DESCRIPTION OF DRAWINGS

Further aspects of the invention will appear from the appended claims and from the following detailed description given with reference to the appended drawings.

FIG. 1 is a simplified perspective view illustrating a method for connecting an antenna wire to a semiconductor die according to an embodiment of the invention; and

FIG. 2 is an RFID transponder having a semiconductor die that is connected to an antenna wire, according to an embodiment of the invention.

### DETAILED DESCRIPTION OF EXAMPLE EMBODIMENTS

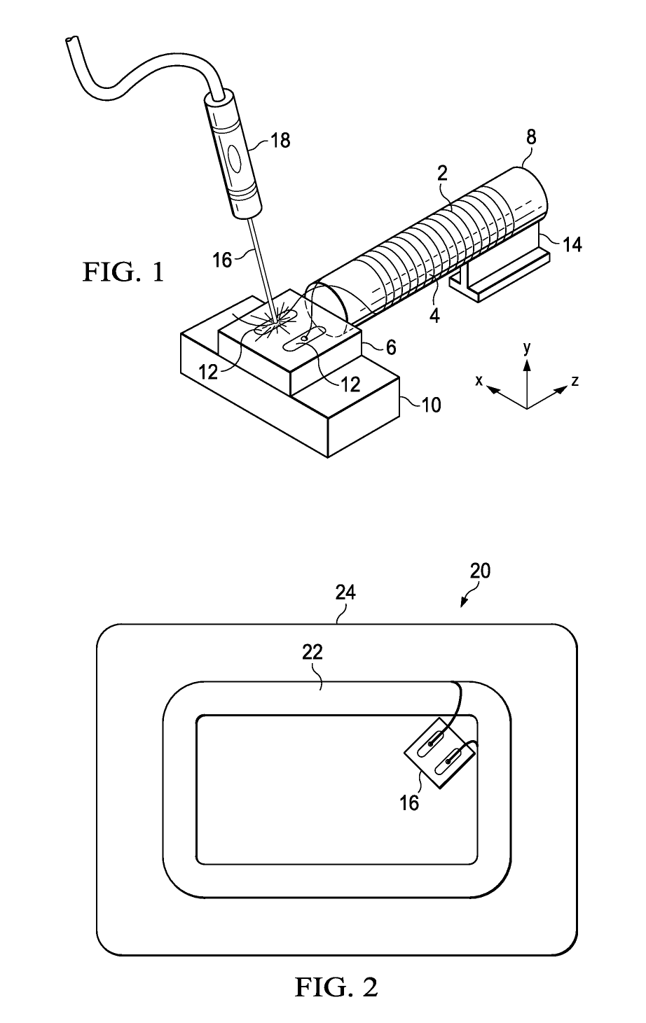

FIG. 1 is a simplified perspective view showing a system for connecting the winding wire 2 of an antenna 4 to a die 6. The winding wire 2 of the antenna 4 is located on a suitable core 8, preferably a ferrite core. The principles of connecting the antenna's winding wire 2 to the die 6 are not limited to an antenna 4 having the depicted structure. Other winding wires 2 may be connected to the die 6 in the same way.

The semiconductor die 6 is located on a positioning stage 10 for positioning the die 6 relative to the antenna 4 and a connecting end of the winding wire 2. The die 6 comprises solderable contact areas 12, preferably a metal plating made from a nickel based alloy, e.g., a NiAu or a NiSn alloy. The solderable contact areas are positioned underneath the soldering end of the winding wire 2 of the antenna 4 with the help of the positioning stage 6. This is preferably done automatically. A suitable solder material, preferably a lead and flux free solder alloy, may be placed on top of the solderable contact areas 12. The antenna 4 is held by a suitable holder 14 and the die 6 is positioned relative to it. Also, the other way round, the antenna 4 may be positioned by a suitable positioning stage and the die 6 may be fixed in a suitably jig.

According to the embodiment of FIG. 1, soldering is performed with the help of a laser 18, i.e., a fiber laser. Optics for guiding and forming an emitted laser radiation 16 are not depicted for clarity reasons. The laser radiation 16 is coupled to the soldering area and the necessary heat for soldering the die 6 to the winding wire 2 is transferred. Other connecting techniques that do not provide the necessary heat input by plastic mechanical deformation onto the solderable contact area 12 or the antenna's winding wire 2, i.e. its soldering end, are also applicable. Due to empirical analysis, it has been found that hot stamping soldering or ultrasonic compression welding are also suitable techniques.

The die 6 may be attached to the positioning stage 10 with the help of a vacuum holder that is preferably integrated in the positioning stage 10. For connecting the winding wire 2 to the solderable contact area 12 of the die 6, the die will be placed by a die picker onto the positioning stage 10 and held by a vacuum holder in position. Preferably the die 6 may be aligned automatically. The die can be placed very easy and is further aligned automatically underneath the winding wire 2 of the antenna 4 which leads to a fast process.

For support of the soldering process, the positioning stage may be heatable. This may be advantageous in combination with the hot stamping solder process. According to another alternative embodiment, ultrasonic compression welding may be used to connect the winding wire with the solderable contact area 12 of the die 6.

Prior to the soldering process, the insulation of the winding wire 2 needs to be stripped off. This may be done with the help of the laser. Stripping the wire's insulation, with the help of the laser's radiation, significantly reduces the stress to the soldering end of the winding wire 2. Residual stress in this part of the winding wire may also lead to stress in the connecting area. By reducing the stress to the winding wire 2, the risk of further stress impact to the soldering area between the winding wire 2 and the solderable contact area 12 of the die 6 may be minimized.

FIG. 2 shows an RFID transponder 20 having an antenna 22 that is connected to a die 6 with the help of the method according to an embodiment of the invention. The RFID transponder 20 has a higher reliability due a reliable electrical connection between the antenna 22 and the die 6.

Although the invention has been described in detail, it should be understood that various changes, substitutions and alterations can be made thereto without departing from the spirit and scope of the invention as defined by the appended claims.

1. An RFID transponder comprising:
a semiconductor die having a solderable contact area; and
an antenna made from a winding wire, wherein the winding wire is soldered to the contact area and the solderable contact area is made from a nickel based alloy.

2. The RFID transponder according to claim 1, wherein the nickel based alloy is NiAu or NiSn.

3. The RFID transponder according to claim 1, wherein the solder contact between the winding wire and the solderable contact area is made by laser soldering, hot stamping soldering or ultrasonic compression welding.

4. The RFID transponder according to claim 2, wherein the solder contact between the winding wire and the solderable contact area is made by laser soldering, hot stamping soldering or ultrasonic compression welding.

5. The RFID transponder according to claim 1, wherein the solderable contact area comprises a Sn finish.

6. The RFID transponder according to claim 2, wherein the solderable contact area comprises a Sn finish.

7. The RFID transponder according to claim 3, wherein the solderable contact area comprises a Sn finish.

8. The RFID transponder according to claim 1, wherein the winding wire insulation is stripped off using a laser.

9. A method for connecting a semiconductor die to a winding wire of an antenna comprising:
providing a solderable contact area on the die made from a nickel based alloy;
soldering the winding wire to the solderable contact area by using a hot stamping solder process or by ultrasonic compression welding.

10. The method of connecting a semiconductor die to a winding wire of an antenna according to claim 9, further comprising positioning the die and the winding wire relative to each other with a positioning stage, wherein the die is fixed to the positioning stage with the help of a vacuum holder.

11. The method of connecting a semiconductor die to a winding wire of an antenna according to claim 9, wherein the step of soldering is performed by laser soldering.

12. The method of connecting a semiconductor die to a winding wire of an antenna according to claim 9, further comprising the step of stripping off the winding wire insulation with the laser.

13. A method for connecting a semiconductor die to a winding wire of an antenna comprising:
providing a solderable contact area on the die made from a nickel based alloy;
soldering the winding wire to the solderable contact area by using a contact free connecting method.

14. The method of connecting a semiconductor die to a winding wire of an antenna according to claim 13, wherein the step of soldering is performed by laser soldering.

15. The method of connecting a semiconductor die to a winding wire of an antenna according to claim 14, further comprising the step of stripping off the winding wire insulation with the laser.

16. The method of connecting a semiconductor die to a winding wire of an antenna according to claim 13, further comprising positioning the die and the winding wire relative to each other with a positioning stage, wherein the die is fixed to the positioning stage with the help of a vacuum holder.
